(19) United States
(12) Patent Application Publication
(10) Pub. No.: US 2019/0172782 A1
(43) Pub. Date: Jun. 6, 2019

(54) PACKAGING SUBSTRATE FOR SEMICONDUCTOR DEVICES, CORRESPONDING DEVICE AND METHOD

(71) Applicant: STMicroelectronics S.r.l., Agrate Brianza (MB) (IT)

(72) Inventor: Federico Giovanni ZIGLIOLI, Pozzo d'Adda (IT)

(73) Assignee: STMicroelectronics S.r.l., Agrate Brianza (MB) (IT)

(21) Appl. No.: 16/269,300

(22) Filed: Feb. 6, 2019

Related U.S. Application Data
(62) Division of application No. 15/159,212, filed on May 19, 2016.

(30) Foreign Application Priority Data
Nov. 10, 2015 (IT) 102015000071060

(51) Int. Cl. H01L 23/498; H05K 1/02; H05K 1/11; H05K 3/10; H05K 3/20; H01L 23/00; H05K 3/40; H01L 21/48

(52) U.S. Cl. CPC H01L 23/49838; H01L 2924/06; H05K 1/0295; H05K 1/112; H05K 3/107; H05K 3/205; H01L 24/49; H05K 3/4046; H01L 21/4846; H01L 24/32; H01L 24/73; H05K 1/0287; H05K 3/4015; H01L 2224/48227; H01L 2224/48106; H01L 2224/48091; H01L 2224/32225; H01L 2924/00014; H01L 24/48; H05K 2203/308; H05K 2203/1476; H05K 2203/1461; H05K 2203/143; H05K 2203/1189; H05K 2203/0369; H05K 2203/0361; H05K 2203/0338; H05K 2203/025; H05K 2201/10378; H05K 2201/09945; H05K 2201/09409; H01L 2924/14; H01L 2924/01079; H01L 2924/01078; H01L 2924/01047; H01L 2924/01028; H01L 2924/01029; H01L 2924/01013; H01L 2924/01006; H01L 2924/01044; H01L 2924/0538; H01L 2924/07025; H01L 2924/15747; H05K 1/0289

(57) ABSTRACT

A substrate for mounting a semiconductor device includes an insulating layer having first and second opposed surfaces defining a thickness. First and second electrically conductive lands are included in the insulating layer. The first electrically conductive lands extend through the whole thickness of the insulating layer and are exposed on both the first and second opposed surfaces. The second electrically conductive lands have a thickness less than the thickness of the insulating layer and are exposed only at the first surface. Electrically conductive lines at the first surface of the insulating layer couple certain ones of the first electrically conductive lands with certain ones of the second electrically conductive lands. The semiconductor device is mounted to the first surface of the insulating layer. Wire bonding may be used to electrically coupling the semiconductor device to certain ones of the first and second lands.

### CROSS REFERENCE TO RELATED APPLICATIONS

This application is a divisional of U.S. patent application Ser. No. 15/159,212, filed May 19, 2016, which claims priority from Italian Application for Patent No. 102015000071060 filed Nov. 10, 2015, the disclosure of which is incorporated by reference.

### TECHNICAL FIELD

The description relates to packaging substrates for semiconductor devices.

One or more embodiments may be applied for example to integrated circuits (ICs).

### BACKGROUND

Due to the continuing growth of the semiconductor device industry, a steady demand exists for improved packaging options, for example solutions which may permit using a same substrate/lead frame for different dice with specific size and a wider range of input/output (I/O) connections.

### SUMMARY

According to one or more embodiments, a packaging substrate for semiconductor devices is provided.

One or more embodiments may also relate to a corresponding device (for example an integrated circuit) as well as to a corresponding method.

One or more embodiments may provide a package which includes metal lands with two different thicknesses; one type of land with two faces exposed with respect to the insulating compound layer, the other type having only one face exposed with respect to the insulating layer.

In one or more embodiments, a printed metal track (conductive line) may connect a top surface of two or more metal lands and a wire bonding, thus creating an interconnection between the die and the metal track.

One or more embodiments may offer one or more of the following advantages: a need no longer exists for a specific lead frame/substrate for each device; wire bonding can be provided on a standard lead finishing; a high flexibility if provided in terms of routing solutions; and applicability to leaded packages with dedicated pre-molded carriers.

In an embodiment, a substrate for mounting semiconductor devices comprises: an electrically insulating layer having first and second opposed surfaces, the electrically insulating layer having a thickness between said first and second opposed surfaces, the substrate including first and second electrically conductive lands in said electrically insulating layer, wherein: said first lands extend through a whole thickness of said electrically insulating layer and are exposed on both the first and second opposed surfaces of the electrically insulating layer, and said second lands have a thickness less than the thickness of the electrically insulating layer and are exposed only at the first surface of the electrically insulating layer.

In an embodiment, a semiconductor device includes: a substrate including an electrically insulating layer having first and second opposed surfaces, the electrically insulating layer having a thickness between said first and second opposed surfaces, the substrate including first and second electrically conductive lands in said electrically insulating layer, wherein: said first lands extend through a whole thickness of said electrically insulating layer and are exposed on both the first and second opposed surfaces of the electrically insulating layer, and said second lands have a thickness less than the thickness of the electrically insulating layer and are exposed only at the first surface of the electrically insulating layer; at least one semiconductor die mounted on said first surface of the electrically insulating layer, and wire bonding electrically coupling said at least one semiconductor die with selected ones of said first and second lands.

In an embodiment, a method comprises: etching a first surface of an electrically conductive laminar carrier to produce raised portions corresponding to locations of first lands and produce a recessed surface, further etching said recessed surface of said laminar carrier to produce indented portions between raised portion corresponding to locations of second lands, molding onto said first surface of said laminar carrier an electrically insulating molding material that penetrates into said indented portions and covers said recessed surface of said laminar carrier at said raised portions, and removing said electrically conductive laminar carrier at a second surface opposite the first surface to expose the molding compound which penetrated into said indented portions.

In an embodiment, a method comprises: growing first and second electrically conductive formations on a first surface of a sacrificial carrier layer, wherein said first electrically conductive formations correspond to locations of first lands, and wherein said second electrically conductive formations correspond to locations of seconds lands, applying a mask material on said first surface of said sacrificial carrier layer to penetrate into indented portions between said second electrically conductive formations and further covers said second electrically conductive formations while leaving said first electrically conductive formations uncovered, further growing electrically conductive material onto said uncovered first electrically conductive formations, molding onto said first surface of said sacrificial carrier layer an electrically insulating molding material that fills space between the further grown electrically conductive material, and removing the sacrificial carrier layer.

### BRIEF DESCRIPTION OF THE DRAWINGS

One or more embodiments will now be described, by way of example only, with reference to the annexed figures, wherein:

FIG. 1, including portions a) to e), show process steps;

FIG. 2, including portions a) to f), show process steps;

FIG. 3, including portions a) to c), show process steps;

FIGS. 4 and 5 are plan views of semiconductor devices; and

FIGS. 6 and 7 are further plan views exemplary of possible substrate customization.

It will be appreciated that for the sake of simplicity of representation the various figures may not be drawn to a same scale.

### DETAILED DESCRIPTION

In the ensuing description, one or more specific details are illustrated, aimed at providing an in-depth understanding of examples of embodiments. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments.

The references used herein are provided merely for convenience and hence do not define the extent of protection or the scope of the embodiments.

One or more embodiments may take advantage of the availability of metal ink printers (for example aerosol ink jet printers).

In the area of electronics these printers are primarily used to produce metal tracks (that is, conductive lines) on substrates such as for example printed circuit boards—PCBs.

Aerosol jet systems may reliably produce ultra-fine feature circuitry beyond the capabilities of for example thick-film and ink jet processes.

For instance, many materials can be “written” with a resolution of down to 20 μm, with a total length of each interconnect of for example 1.5 mm with a throughput for a single nozzle reaching up to 5,000 interconnects per hour. An aerosol jet print head is highly scalable and may support for example 2, 3, 5, or more nozzles at a time, pitch dependent, enabling throughputs as high as 25,000 interconnects per hour or more.

Just by way of example, materials adapted to be printed may include metals (for example gold, platinum, silver, nickel, copper, aluminim), resistive ink materials (for example carbon, ruthenate), non-metallic conductors (for example single wall carbon nanotubes, multi wall carbon nanotubes, PEDOT:PSS), dielectrics and adhesive materials (for example polyimide, polyvinylpyrrolidone (PVP), Teon AF, SU-8 Adhesives, opaque coatings, UV adhesives UV acrylics), semiconductors (for example organic semiconductors), solvents, acids and bases, photo- and etch-resists, DNA, proteins, enzymes.

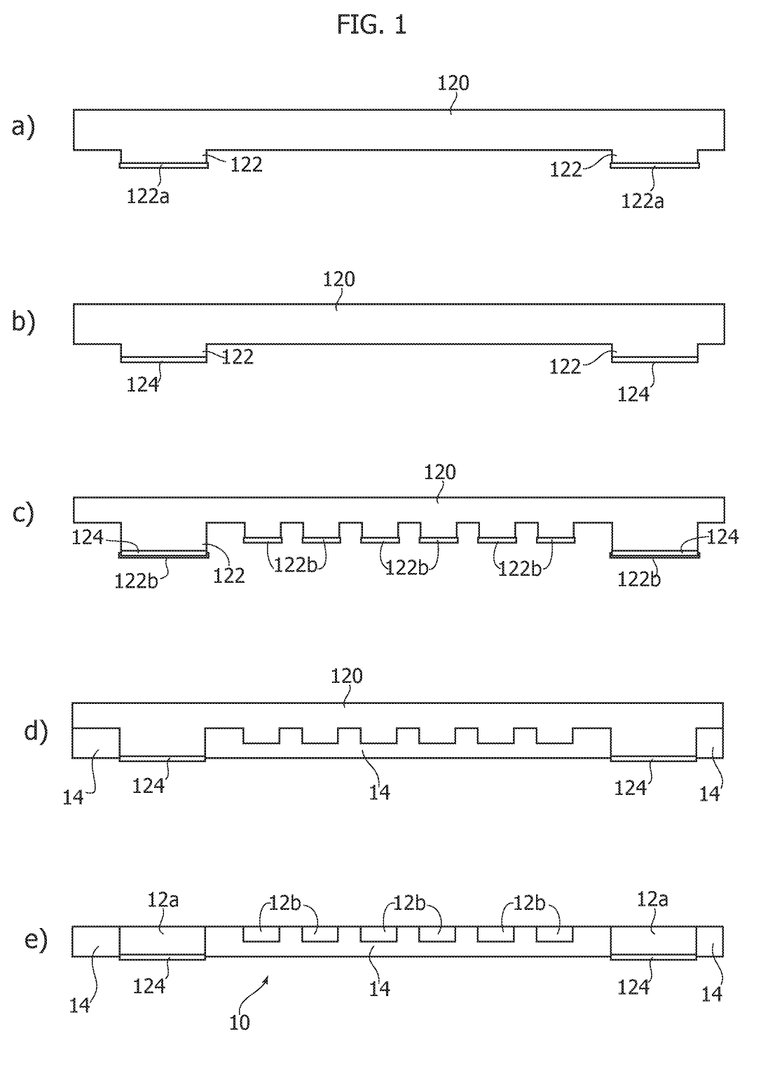

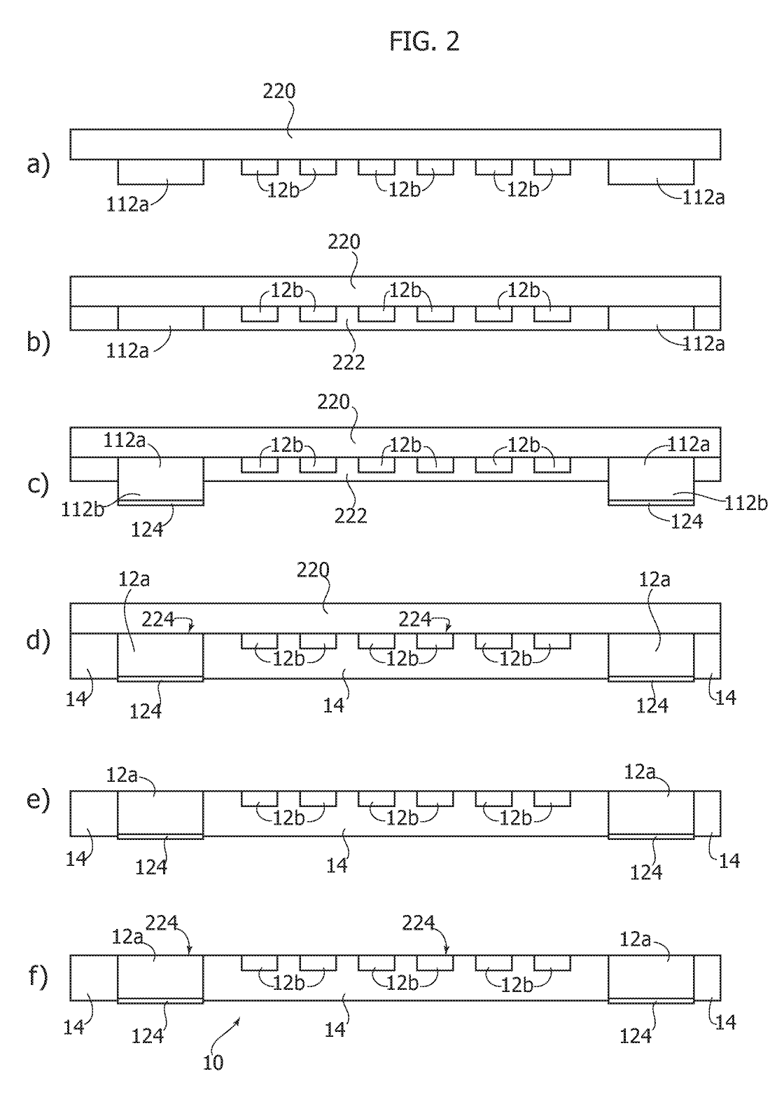

The diagrams of FIGS. 1 and 2 are exemplary of ways of producing a package substrate 10 where the substrate includes two types of electrically conductive (for example metal) portions or “lands” with two different thicknesses:
one type of land, 12a, is thick enough to have two opposed faces which are exposed on both surfaces (upper and lower, in the figures) of an insulating compound layer 14,
the other type of land, 12b, is less thick and thus has only one face exposed on one surface (for example the upper one in the figures) of the insulating compound layer 14.

The sequence of steps a) to e) of FIG. 1 is exemplary of an etching-based process for producing such a substrate, the process including for example:
step a) a first etching of a laminar for example copper carrier 120 while covering certain portions of one (here, lower) side of the carrier with a resist layer 122a so that raised portions 122 intended to form “precursors” of the first lands 12a remain at that side as a result of etching;
step b) forming leads 124, for example by plating the surfaces of the raised portions 122;
step c) a second etching of the copper carrier 120 by covering with a resist layer 122b the plated surfaces 124 of the raised portions 122 as well as selected areas of the carrier 120 so that indented portions are formed in the carrier 120 between the areas selectively covered by the resist layer 122b;
step d) pre-molding onto the “sculptured” (here, lower) surface of the carrier 120 an electrically insulating package molding compound 14 (of any known type suitable for that purpose) so that the compound 14 covers the carrier surface between the raised portions 122 (first lands 12a) while also penetrating into the indented portions formed between the areas previously covered by the resist layer 122b (which may be removed before molding the package molding compound 14 onto the carrier 120);
step e) removing (for example by grinding) the carrier material at the opposed (here, upper) side of the carrier 120 for a thickness enough to expose the (solidified) molding compound 14 at the indented portions.

As a result, the plated surfaces 124 of the raised portions 122 will form—at the first lands 12a—for example an array of substrate pads (for example plated pads) 124 at one (here lower) surface or side of the resulting substrate, while the remainder portions of the carrier 120 selectively covered by the resist layer 122b (see portion c) of FIG. 1) will form for example an array of second lands 12b at the other (here upper) surface or side of the resulting substrate, namely an for example matrix array of bonding pads mutually isolated by the compound 14 penetrated into the indented portions therebetween.

Technologies and apparatus for use in performing each of the steps a) to e) of FIG. 1 are known in the art, which makes it unnecessary to provide a more detailed description herein.

The sequence of steps a) to f) of FIG. 2 is exemplary of a growth-based process for producing a similar substrate, the process including for example:
step a) a first growing (for example chemically) of electrically conductive (for example copper) formations 112a and 12b on one side (here lower) of a “sacrificial” carrier 220 of for example inox steel (for example 100 micron-100.10−6 m) or other suitable metal alloys with the formations 12b (for example already the second lands) at least slightly thinner than the formations 112a (these latter being intended to form “precursors” of the first lands 12a);
step b) masking with a mask material 222 the side of the carrier 220 onto which the formations 112a, 12b have been grown with a masking material of a thickness enough to cover the formations 12b while leaving the formations 112a uncovered;
step c) a second growing (for example chemically) of electrically conductive (for example copper) material 112b onto the formations 112a in order to complete the first lands 12a by forming leads 124 for example by plating at the surfaces of the first lands 12a thus completed;
step d) molding onto the “sculptured” (here again, lower) surface of the carrier 220, optionally after removing the mask material 222, an electrically insulating package molding compound 14 (of any known type suitable for that purpose) so that the compound 14 covers the carrier surface between the raised portions (first lands 12a) while also penetrating into the indented portions are formed between the second lands 12b;
step e) removing (for example by peeling) the sacrificial carrier material 220.

As a result, the plated surfaces 124 of the raised portions 122 will form—at the first lands 12a—for example an array of substrate pads (for example plated pads) 124 at one (here lower) surface or side of the resulting substrate, while the second lands 12b at the other (here upper) surface of the resulting substrate will form a for example matrix array of bonding pads mutually isolated by the compound 14 penetrated into the indented portions therebetween.

A final step f) of top surface finishing may then be performed as schematically indicated at 224. It will be understood that a same top surface finishing step may be performed after the step e) of FIG. 1.

Here again, technologies and apparatus for use in performing each of the steps a) to f) of FIG. 2 are known in the art, which makes it unnecessary to provide a more detailed description herein.

In one or more embodiments, both processes as exemplified in FIGS. 1 and 2 may make it possible to produce a substrate for mounting semiconductor devices, the substrate including an electrically insulating layer 14 having first and second opposed surfaces (upper and lower, in the figures), the electrically insulating layer 14 having a thickness between the first and second opposed surfaces, the substrate including (for example an array of) first electrically conductive lands 12a and (for example an array of) second electrically conductive lands 12b (formed for example embedded) in the electrically insulating layer 14, wherein:
the first lands 12a extend through the whole thickness of the electrically insulating layer 14 and are exposed on both the first and second opposed surfaces of the electrically insulating layer 14, and
the second lands 12b have a thickness less than the thickness of the electrically insulating layer 14 and are exposed only at the first (for example upper) surface of the electrically insulating layer 14.

In one or more embodiments, the first lands 12a and the second lands 12b may be exposed to the first surface of the electrically insulating layer 14 flush therewith: see for example FIG. 1, portion e) or FIG. 2, portions e) and f).

In one or more embodiments, the first lands 12a may include contact pads 124 at the second surface of the electrically insulating layer 14.

In one or more embodiments as exemplified in FIG. 1, producing a substrate 10 as exemplified in the foregoing may include:
etching a surface of an electrically conductive laminar carrier (for example 120) by producing raised portions to provide said first lands (for example 12a),
further etching said surface of said laminar carrier to provide indented portions in said carrier between said second lands (for example 12b),
molding onto said surface of said laminar carrier an electrically insulating molding material (for example 14), whereby the molding material covers said surface of said laminar carrier between said raised portions while also penetrating into said indented portions, and
removing said electrically conductive laminar carrier material at the surface opposed said etched surface to expose the molding compound at said indented portions.

In one or more embodiments as exemplified in FIG. 2, producing a substrate 10 as exemplified in the foregoing may include:
growing first and second electrically conductive formations on a surface of a sacrificial carrier layer (for example 220), said second electrically conductive formations forming said seconds lands (for example 12b),
applying a mask material (for example 222) on said surface of said sacrificial carrier layer to cover said second formations while leaving said first formations uncovered,
further growing electrically conductive material onto said first formations to complete said first lands (for example 12a),
molding onto said surface of said sacrificial carrier layer an electrically insulating molding material (for example 14) to cover said sacrificial carrier layer between said first lands and penetrate into the indented portions between said second lands, and
removing the sacrificial carrier layer.

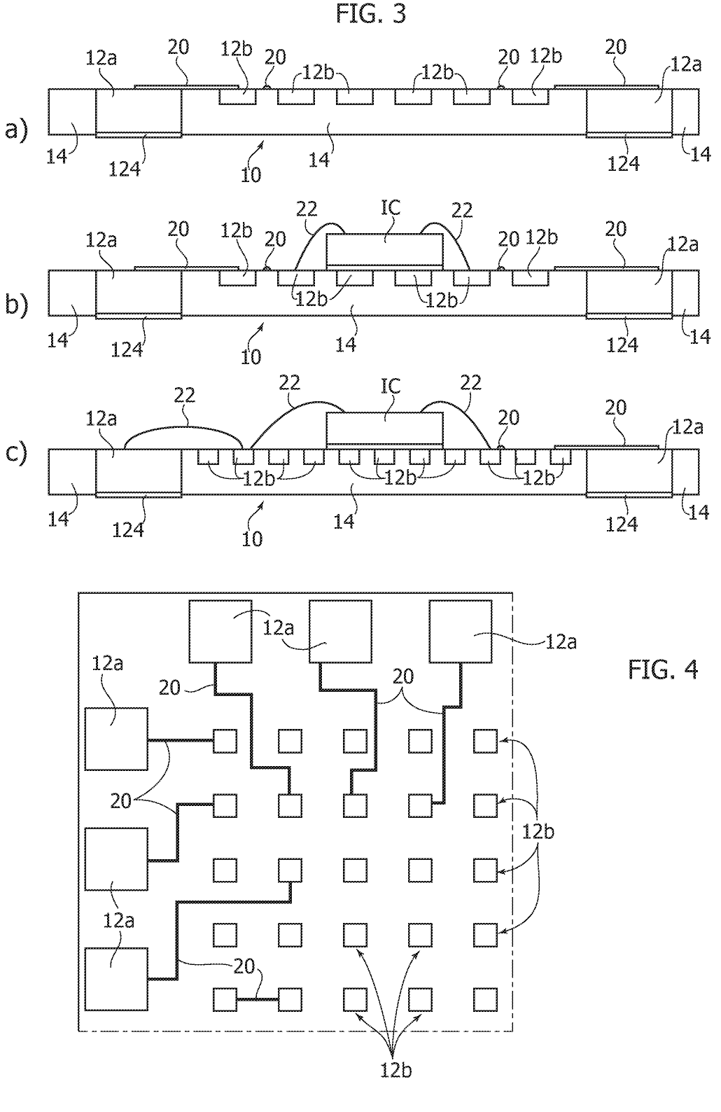

Whatever the approach adopted, in one or more embodiments, the structures obtained as a result of the steps exemplified in FIG. 1 or FIG. 2 may be subjected to further steps as exemplified in FIG. 3 aiming at producing a package with a substrate 10 where for example metal tracks 20 (electrically conductive lines) may be printed, possibly by ink jet/aerosol ink jet printing, to connect at their top surfaces (for example at the upper surface of the insulating layer 14) one more lands 12a, 12b with wire bonding 22 to provide electrical connection between a semiconductor device (for example an integrated circuit die IC) and such a conductive lines or tracks.

It will be appreciated that, in order to highlight the intrinsic flexibility of one or more embodiments, step c) of FIG. 3 deliberately shows a different pattern of second lands 12b with respect to portion b).

One or more embodiments may thus include electrically conductive lines 20 at the first (for example upper) surface of the electrically insulating layer 14 for coupling selected ones of the first lands 12a with selected ones of the second lands 12b.

One or more embodiments may thus provide a semiconductor device including a substrate as exemplified herein, with one or more semiconductor dice IC on the first surface of the electrically insulating layer 14, wire bonding 22 being provided for electrically coupling the semiconductor die/dice IC with selected ones of the first lands 12a and/or second lands 12b.

In one or more embodiments, ink printed tracks or lines 20 may have a width of 50-100 micron (50-100.10⁻⁶ m) with multi-layer thickness of 10-20 micron (10-20.10⁻⁶ m), for example for those applications where lower resistivity may be desirable for a specific I/O, with a wire adapted to bridge from different pads (with proper dimensions).

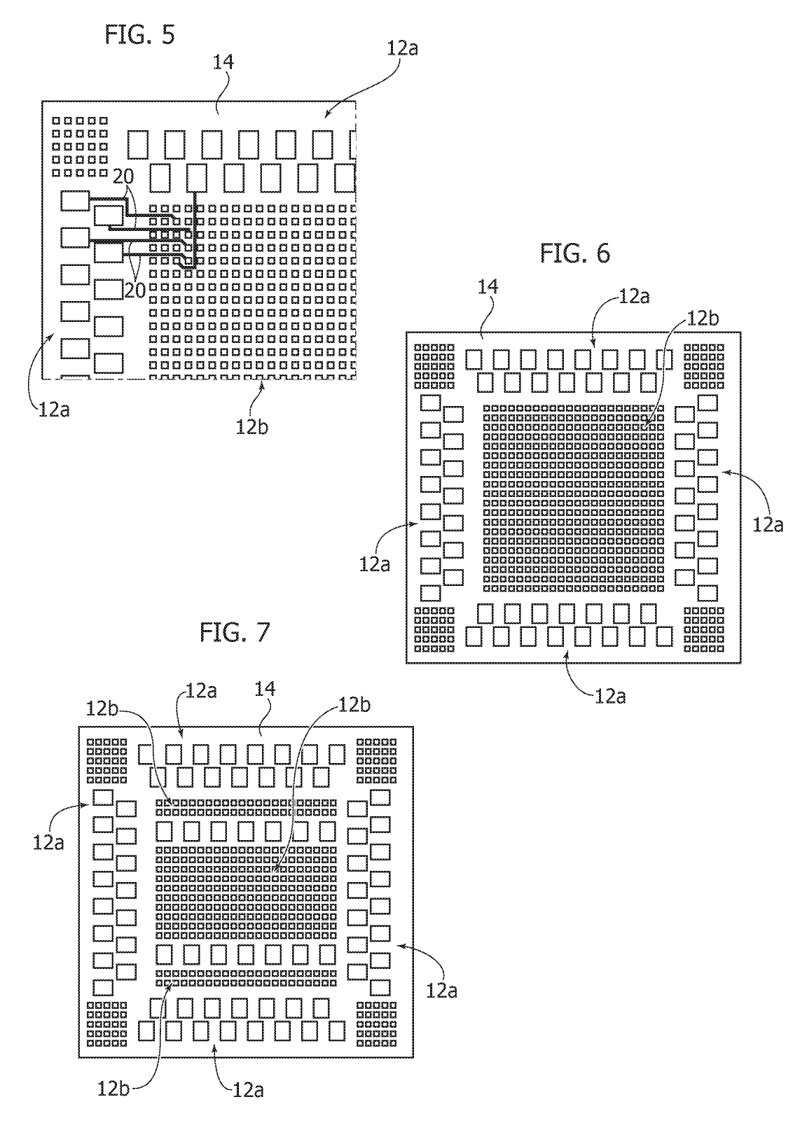

FIGS. 4 and 5 illustrate some schematic examples and possibilities for metal ink printing routing over the arrays 12a, 12b which may be based on specific die requirements for example metal track 100-20 micron (100-20.10⁻⁶ m), pitch 50 micron (50.10⁻⁶ m).

FIGS. 6 and 7 illustrate some possible examples of substrate customization. Based for example on the product portfolio, die size and I/O requirements, a “universal” substrate design may be defined to comply with a large number of applications.

One or more embodiments as exemplified herein may thus offer one or more of the following advantages:
a same substrate/lead frame may be used for different dice with specific size and a wider range of I/O connections;
flexibility of use;
rapid sampling for testing and prototyping;
routing according to specific requirements is facilitated; and
ball-grid array (BGA) design can be elaborated also on lead frame (LF) packages.

Without prejudice to the underlying principles, the details and embodiments may vary, even significantly, with respect to what has been described by way of example only without departing from the extent of protection.

The extent of protection is defined by the annexed claims.

1. A method, comprising:
etching a first surface of an electrically conductive laminar carrier to produce first raised portions corresponding to locations of first lands and produce a recessed surface,
further etching said recessed surface of said electrically conductive laminar carrier to produce indented portions between second raised portions corresponding to locations of second lands,
molding onto said first surface of said electrically conductive laminar carrier an electrically insulating molding material that penetrates into said indented portions and covers said recessed surface of said laminar carrier at said second raised portions, and
removing a portion of said electrically conductive laminar carrier at a second surface opposite the first surface to expose the molding compound which penetrated into said indented portions.

2. The method of claim 1, wherein removing comprises reducing a thickness of the electrically conductive laminar carrier from the second surface.

3. The method of claim 1, wherein portions of said electrically conductive laminar carrier which remain after the step of removing define the first lands having a first thickness and the second lands having a second thickness less than the first thickness.

4. The method of claim 1, wherein removing produces the first and second lands as structures which are insulated from each other by the molding compound which penetrated into said indented portions and covered said recessed surface of said laminar carrier.

5. The method of claim 1, further comprising forming metal tracks on a top surface resulting from the step of removing, said metal tracks electrically interconnecting at least one second land to another second land.

6. The method of claim 5, wherein forming the metal tracks comprises printing lines made of conductive material on the top surface.

7. The method of claim 6, wherein printing comprises ink jet printing.

8. The method of claim 6, wherein the lines have a width in a range of 50-100 microns and a thickness in a range of 10-20 microns.

9. The method of claim 1, further comprising forming metal tracks on a top surface resulting from the step of removing, said metal tracks electrically interconnecting at least one first land to at least one second land.

10. The method of claim 9, wherein forming the metal tracks comprises printing lines made of conductive material on the top surface.

11. The method of claim 10, wherein printing comprises ink jet printing.

12. The method of claim 10, wherein the lines have a width in a range of 50-100 microns and a thickness in a range of 10-20 microns.

13. A method, comprising:
growing first and second electrically conductive formations on a first surface of a sacrificial carrier layer, wherein said first electrically conductive formations correspond to locations of first lands, and wherein said second electrically conductive formations correspond to locations of seconds lands,
depositing an insulating material on said first surface of said sacrificial carrier layer to penetrate into indented portions between said second electrically conductive formations and cover said second electrically conductive formations while leaving said first electrically conductive formations uncovered, and
removing the sacrificial carrier layer to produce a substrate including said first and second lands insulated from each other by the insulating material and having exposed surfaces of the both the first and second lands at a top surface of the substrate and exposed surfaces of only the first lands at a second surface of the substrate opposite the first surface.

14. The method of claim 13, wherein the first lands have a first thickness and the second lands have a second thickness less than the first thickness.

15. The method of claim 13, further comprising forming metal tracks on the top surface, said metal tracks electrically interconnecting at least one second land to another second land.

16. The method of claim 15, wherein forming the metal tracks comprises printing lines made of conductive material on the top surface.

17. The method of claim 16, wherein printing comprises ink jet printing.

18. The method of claim 16, wherein the lines have a width in a range of 50-100 microns and a thickness in a range of 10-20 microns.

19. The method of claim 13, further comprising forming metal tracks on a top surface, said metal tracks electrically interconnecting at least one first land to at least one second land.

20. The method of claim 19, wherein forming the metal tracks comprises printing lines made of conductive material on the top surface.

21. The method of claim 20, wherein printing comprises ink jet printing.

22. The method of claim 20, wherein the lines have a width in a range of 50-100 microns and a thickness in a range of 10-20 microns.

23. The method of claim 13, wherein depositing the insulating material comprises applying a mask material on said first surface of said sacrificial carrier layer to penetrate into indented portions between said second electrically conductive formations and cover said second electrically conductive formations while leaving said first electrically conductive formations uncovered, the method further comprising:
further growing electrically conductive material onto said uncovered first electrically conductive formations, and
molding onto said first surface of said sacrificial carrier layer an electrically insulating molding material that fills space between the further grown electrically conductive material.
